(19) United States
(12) Patent Application Publication
(10) Pub. No.: US 2015/0116950 A1
(43) Pub. Date: Apr. 30, 2015

(54) COIL COMPONENT, MANUFACTURING METHOD THEREOF, COIL COMPONENT-EMBEDDED SUBSTRATE, AND VOLTAGE ADJUSTMENT MODULE HAVING THE SAME

(71) Applicant: SAMSUNG ELECTRO-MECHANICS CO., LTD., Suwon-Si (KR)

(72) Inventors: Ji No YOO, Suwon-Si (KR); Han KIM, Suwon-Si (KR); Won Gi KIM, Suwon-Si (KR); Suk Hyeon CHO, Suwon-Si (KR)

(21) Appl. No.: 14/524,940

(22) Filed: Oct. 27, 2014

(30) Foreign Application Priority Data
Oct. 29, 2013 (KR) 10-2013-0129526
Feb. 21, 2014 (KR) 10-2014-0020125

(51) Int. Cl. H01F 27/28; H05K 7/02; H01F 41/02; H01F 27/29

(52) U.S. Cl. CPC H01F 27/2804; H01F 27/29; H05K 7/02; H01F 41/02; H01F 2027/2809
USPC 361/728; 336/200; 336/192; 29/607

(57) ABSTRACT

A coil component may be capable of being easily manufactured and significantly decreasing direct current (DC) resistance of its wiring. The coil component may include a coil assembly including a core substrate and coil patterns formed on the core substrate; and a magnetic material part embedding the coil assembly therein.

### CROSS-REFERENCE TO RELATED APPLICATIONS

This application claims the benefit of Korean Patent Application No. 10-2013-0129526 filed on Oct. 29, 2013, and 10-2014-0020125 filed on Feb. 21, 2014, with the Korean Intellectual Property Office, the disclosures of which are incorporated herein by reference.

### BACKGROUND

The present disclosure relates to a coil component, a manufacturing method thereof, and a coil component-embedded substrate, and more particularly, to a coil component able to be easily manufactured and having a significantly decreased direct current (DC) resistance component in wiring, a manufacturing method thereof, a coil component-embedded substrate, and a voltage adjustment module having the same.

Recently, in accordance with the slim size and light weight of mobile devices, miniaturization of components mounted in such mobile devices and multifunctionalization of a substrate have rapidly progressed. (“Multifunctionalization of the substrate,” as used herein, refers to passive components or active components being embedded in the substrate or some functions thereof being implemented by patterns of the substrate, in addition to electrical connections being formed between the respective components, a basic role of the substrate.)

For example, various attempts to embed elements such as capacitors, resistors, coils, and the like, in substrates, have been undertaken.

Technology for embedding a coil or an inductor in a substrate may be divided into an arrangement of forming a shape of a coil with a wiring pattern in a process of manufacturing the substrate to complete the coil and an arrangement of separately manufacturing a coil component and then embedding the coil component in the substrate.

However, the majority of coil components according to the related art as described above and substrates having the same embedded therein have aimed at inductors having a low level of inductance. That is, an inductor embedded in a substrate according to the related art may perform the functions of a basic inductor. However, it is somewhat difficult for such an inductor embedded in a substrate according to the related art to be used as a power supply inductor (or power inductor) requiring a high level of inductance.

Since a power inductor has high inductance (on the level of several μHs), low direct current (DC) resistance, and a high rating current, it is somewhat difficult to implement such a power inductor in a substrate. Nevertheless, in accordance with a trend toward miniaturization of electronic devices, demand for a power inductor that may be embedded in a substrate or a substrate including the same has gradually increased.

### SUMMARY

An exemplary embodiment in the present disclosure may provide a coil component capable of having a high degree of inductance, being easily manufactured, and being embedded in a substrate, and a manufacturing method thereof.

An exemplary embodiment in the present disclosure may also provide a substrate in which a coil component having a high degree of inductance is embedded, and a voltage adjustment module having the same.

According to an exemplary embodiment in the present disclosure, a coil component may include at least one core substrate; at least one internal conductor formed on at least one surface of the core substrate; and a magnetic material part formed outside of the core substrate, wherein the internal conductor has a width at least that of the core substrate.

The core substrate and the internal conductor may be formed in a ring shape.

The magnetic material part may be formed to embed the core substrate and the internal conductor therein.

The internal conductor may be formed on two surfaces of the core substrate, and the internal conductors are electrically connected to each other by at least one connection conductor.

The connection conductor may be formed in a shape of a conductive via penetrating through the core substrate.

The coil component may further include an insulating layer between the internal conductor and the magnetic material part.

The coil component may further include an insulating film between the internal conductor and the magnetic material part.

The coil component may further include an insulating layer between one surface of the internal conductor and the magnetic material part and an insulating oxide film between a side surface of the internal conductor and the magnetic material part.

The magnetic material part may be made of an insulating material containing a magnetic powder or a metal powder.

The coil component may further include an insulating material part on an external surface of the magnetic material part; at least one external electrode on an external surface of the insulating material part; and at least one through via electrically connecting the internal conductor and the external electrode to each other.

The external electrode may be on upper and lower surfaces of the insulating material part.

According to an exemplary embodiment in the present disclosure, a coil component may include at least one core substrate; an internal conductor on at least one surface of the core substrate; and a magnetic material part outside of the core substrate, wherein an external peripheral edge and an inner peripheral edge of the internal conductor have sizes the same as those of the core substrate.

According to an exemplary embodiment in the present disclosure, a manufacturing method of a coil component may include preparing a core substrate having a metal layer formed on at least one surface thereof; processing the core substrate in a ring shape by cutting the core substrate by a pressing method; and forming a magnetic material part outside of the core substrate having the ring shape.

The manufacturing method of a coil component may further include, after the preparing of the core substrate, forming multilayer patterns by processing the core substrate.

The forming of the multilayer patterns may include electrically connecting metal layers respectively formed on both surfaces of the core substrate to each other by forming a connection conductor in the core substrate; and forming separation grooves by removing portions of the metal layers.

In the forming of the separation grooves, the respective separation grooves may be formed in two metal layers while being provided in both sides of the connection conductor.

The manufacturing method of a coil component may further include, after the forming of the separation grooves, forming insulating layers on external surfaces of the metal layers.

The manufacturing method of a coil component may further include, after the processing of the core substrate, forming an insulating film on an external surface of an internal conductor formed by cutting the metal layer.

In the forming of the insulating film, an oxide film may be formed on an exposed surface of the internal conductor.

The manufacturing method of a coil component may further include, after the forming of the magnetic material part outside of the core substrate, forming an insulator layer on an external surface of the magnetic material part.

The manufacturing method of a coil component may further include, after the forming of the insulator layer, forming at least one through via in the insulator layer, the through via being electrically connected to the internal conductor; and forming at least one external electrode on an external surface of the insulator layer, the external electrode being electrically connected to the through via.

According to an exemplary embodiment in the present disclosure, a coil component-embedded substrate may include at least one insulating layer; and a coil component including a core substrate having an internal conductor on at least one surface thereof and a magnetic material part outside of the core substrate and embedded in the insulating layer, the internal conductor having a width at least that of the core substrate.

According to an exemplary embodiment in the present disclosure, a voltage adjustment module may include a substrate; a power inductor including a core substrate having an internal conductor formed on at least one surface thereof and a magnetic material part formed outside of the core substrate and embedded in the substrate, the internal conductor having a width the same as that of the core substrate; and at least one voltage adjusting element mounted on the substrate and electrically connected to the power inductor.

The voltage adjusting element may adjust an amount of voltage provided to a radio frequency (RF) power amplifier depending on a magnitude of a radio signal in an envelope tracking (ET) power amplifier.

Portions of the magnetic material part disposed above and below the core substrate may respectively have a thickness of 50 μm or more.

### BRIEF DESCRIPTION OF DRAWINGS

The above and other aspects, features and other advantages of the present invention will be more clearly understood from the following detailed description taken in conjunction with the accompanying drawings, in which:

FIG. 1 is a perspective view schematically illustrating a coil component according to a first exemplary embodiment in the present disclosure;

FIG. 2 is a perspective view schematically illustrating a coil assembly of the coil component illustrated in FIG. 1;

FIG. 3 is a cross-sectional view of the coil component taken along line A-A of FIG. 1;

FIG. 4A is a perspective view schematically illustrating a coil component according to a second exemplary embodiment in the present disclosure;

FIG. 4B is a cross-sectional view taken along line B-B of FIG. 4A;

FIG. 4C is a perspective view schematically illustrating a coil assembly of the coil component illustrated in FIG. 4A;

FIGS. 5A through 10B are views illustrating a manufacturing method of the coil component according to the first exemplary embodiment in the present disclosure;

FIG. 11 is a cross-sectional view schematically illustrating a coil component-embedded substrate according to a third exemplary embodiment in the present disclosure;

FIGS. 12 through 19 are views illustrating a manufacturing method of the coil component-embedded substrate illustrated in FIG. 11;

FIG. 20 is a cross-sectional view schematically illustrating a coil component-embedded substrate according to a fourth exemplary embodiment in the present disclosure;

FIG. 21 is a cross-sectional view schematically illustrating a coil component-embedded substrate according to a fifth exemplary embodiment in the present disclosure; and

FIG. 22 is a cross-sectional view schematically illustrating a voltage adjustment module according to an exemplary embodiment in the present disclosure.

### DETAILED DESCRIPTION

Hereinafter, embodiments in the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

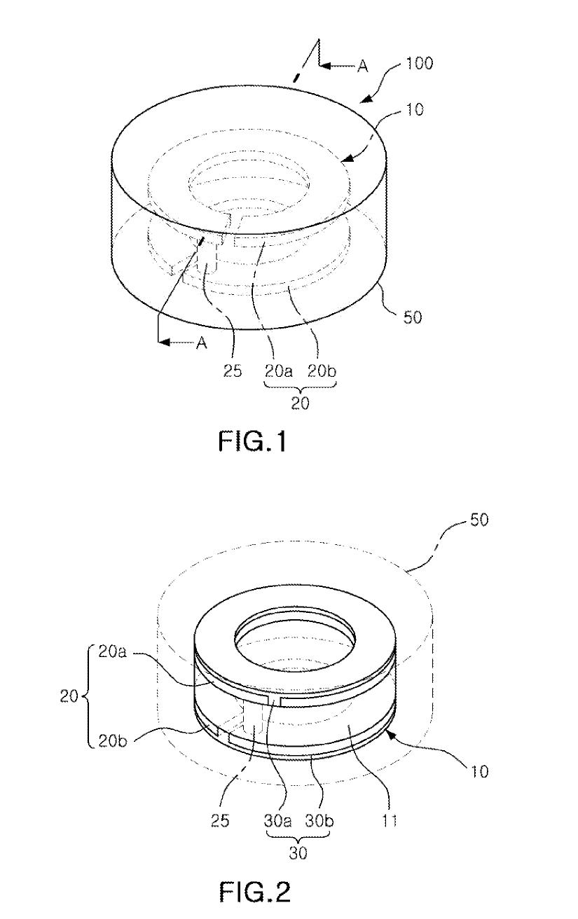

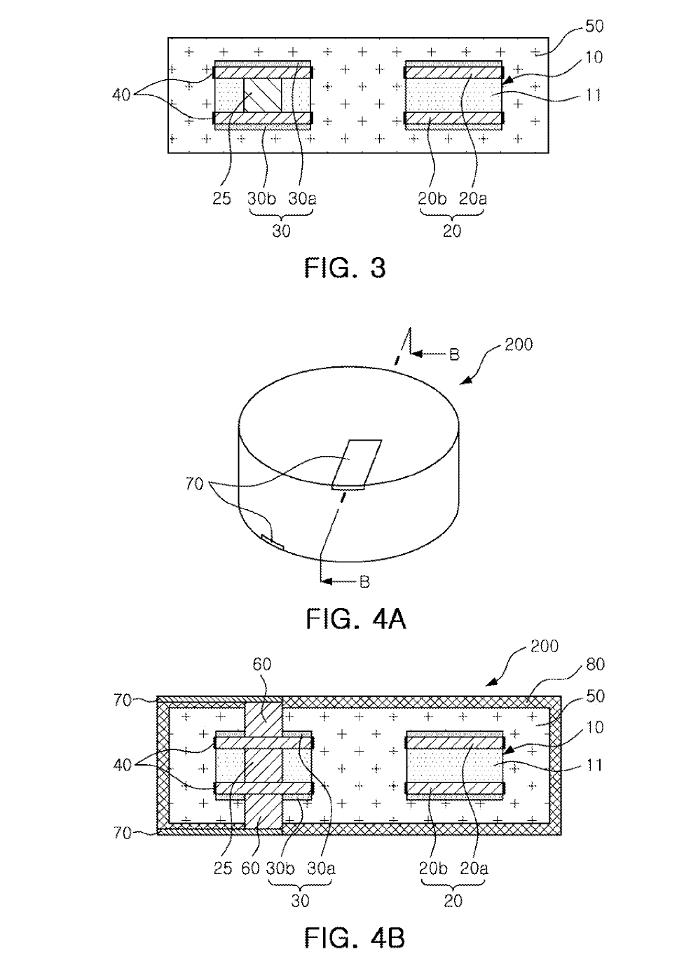

FIG. 1 is a perspective view schematically illustrating a coil component according to a first exemplary embodiment in the present disclosure. FIG. 2 is a perspective view schematically illustrating a coil assembly of the coil component illustrated in FIG. 1. FIG. 3 is a cross-sectional view of the coil component taken along line A-A of FIG. 1. Here, FIG. 1 schematically shows only a coil in the coil assembly embedded in the coil component.

Referring to FIGS. 1 through 3, a coil component 100 according to the exemplary embodiment may include a coil assembly 10 and a magnetic material part 50.

The coil assembly 10 may include a core substrate 11, internal conductors 20, that my be sheet-like, respectively formed on two surfaces of the core substrate 11, and a connection conductor 25 vertically penetrating the core substrate 11 and electrically connecting the respective internal conductors 20 to each other.

The core substrate 11 may be a general insulating substrate. For example, the core substrate 11 may be formed of a resin, for example, polyphenylenesulfide (PPS), liquid crystal polyester (LCP), polybutyleneterephthalate (PBT), FR-4 in which a glass fiber impregnated with an epoxy resin is stacked, or the like.

In addition, a substrate having either rigidity or flexibility may also be used as the core substrate. For example, a printed circuit board (PCB), a glass substrate, a ceramic substrate, a silicon substrate, a film substrate, a substrate on which a metal thin film is formed, or the like, may be used as the core substrate 11.

In addition, although the exemplary embodiment is of a case in which the core substrate 11 configured of a single layer is used, a core substrate 11 configured of multiple layers may also be used, if necessary.

The respective internal conductors 20 may be formed in a ring shape may be sheet-like in configuration and may be stacked with the core substrate 11 interposed therebetween. That is, the core substrate 11 may be interposed between stacked internal conductors 20a and 20b to electrically insulate the internal conductors 20a and 20b from each other. Therefore, in the case in which the core substrate 11 according to the exemplary embodiment has multiple layers, the internal conductors 20 may be disposed on respective layers of the core substrate 11.

Each of the internal conductors 20 may include a disconnected portion as illustrated in FIG. 1. At least one end of one internal conductor 20a or 20b formed by the disconnected portion may be electrically connected to another internal conductor 20a or 20b disposed above or below the internal conductor 20a or 20b by the connection conductor 25.

Therefore, the internal conductors 20 and the connection conductor 25 may generally form a single coil structure.

The connection conductor 25 may electrically connect the internal conductors 20a and 20b disposed on two layers of the core substrate 11 adjacent to each other while vertically penetrating the core substrate 11. Therefore, a conductive via may be used as the connection conductor 25.

The internal conductors 20 according to the exemplary embodiment may have a plan formed in substantially the same manner as that of the core substrate 11. That is, each internal conductor 20 may be formed in a manner in which the remaining portion thereof other than the disconnected portion cover the entirety of one surface of the core substrate 11. Therefore, the pattern width of the internal conductor 20 may be at least the same as the width (or diameter) of the core substrate 11 on which a corresponding pattern is formed.

Therefore, distance between the external peripheral edge and inner peripheral edge of the internal conductor 20 may be substantially the same as or similar to that of the core substrate 11.

Examples of materials of the coil configured as described above may include gold, silver, copper, aluminum, and the like, which are electrical conductors. However, the present disclosure is not limited thereto.

Meanwhile, the exemplary embodiment exemplifies a case in which the internal conductor 20 is formed in a circular ring shape and is sheet-like in configuration. However, the configuration in the present disclosure is not limited thereto, but may be variously modified. For example, the internal conductor 20 may be formed in a polygonal ring shape, an oval shape, a polygonal shape in which edges thereof are formed to be curved, or the like.

In addition, the coil component 100 according to the exemplary embodiment may include insulating layers 30 formed on external surfaces of the respective internal conductors 20. The insulating layers 30 may be formed in order to insulate the internal conductors 20 and the magnetic material part 50 from each other, to be described below. Therefore, the insulating layers 30 may be formed only on the external surfaces of the internal conductors 20 or be formed on the entirety of two surfaces of the core substrate 11 on which the internal conductors 20 are formed as in the exemplary embodiment.

Further, the coil assembly 10 according to the exemplary embodiment may have insulating films 40 formed on side surfaces of the internal conductors 20.

Since each of the internal conductors 20 according to the exemplary embodiment may be sheet-like and formed on the entirety of one surface of the core substrate 11, the internal conductor 20 and the core substrate 11 may have a single cylindrical shape. Therefore, the internal conductor 20 may be exposed to the outside of the core substrate 11.

In this case, the side surface of the internal conductor 20 may be electrically connected to the magnetic material part 50 to be described below. Therefore, in order to prevent an electrical connection between the internal conductor 20 and the magnetic material part 50, the insulating film 40 may be formed on the side surface of the internal conductor 20.

A material of the insulating film 40 may be variously formed, as long as it may electrically insulate the internal conductor 20 and the magnetic material part 50 from each other. For example, an oxide film may be used as the insulating film 40. That is, the oxide film may be formed on the side surface of the internal conductor 20 and be used as the insulating film 40. However, the present disclosure is not limited thereto.

The magnetic material part 50 may be arranged outside of the coil assembly 10 in a form in which the coil assembly 10 is embedded therein. The magnetic material part 50 may be made of a magnetic material, such as ferrite, magnetite, or the like. In addition, the magnetic material part 50 may be made of an insulating material containing a magnetic powder or a metal powder in order to improve performance of the inductor. In this case, at least one of a ferrite powder, a carbonyl iron powder, a molybdenum permalloy powder, and a sendust powder may be used as the magnetic powder or the metal powder. In addition, a thermosetting resin such as an epoxy resin, polyimide, or the like, may be used as the insulating material.

Meanwhile, the described embodiment exemplifies a case in which the coil assembly 10 is entirely embedded in the magnetic material part 50. However, the configuration in the present disclosure is not limited thereto, but may be variously modified, if necessary. For example, the coil assembly 10 may be configured to be partially exposed to the outside of the magnetic material part 50.

In addition, although not shown, a shielding layer may also be formed on an external surface of the magnetic material part 50 in the case in which the magnetic material part 50 is formed of ferrite, or the like. The shielding layer may be formed by applying an insulating material (for example, a resin) containing a magnetic powder or a metal powder to the external surface of the magnetic material part 50.

The coil component 100 according to the exemplary embodiment may be a coil component 100 to be embedded in a substrate. Therefore, the coil component 100 according to the exemplary embodiment does not necessarily include separate external electrodes 70, and may be configured such that an internal coil thereof is electrically connected to wiring patterns 2 of a substrate in a process of manufacturing the substrate after the coil component 100 is embedded in the substrate.

This will be described in detail regarding a manufacturing method of the coil component, below.

In the coil component according to the exemplary embodiment configured as described above, coil patterns (that is, the internal conductors) may be formed to have at lest the same width as that of the core substrate embedded in the magnetic material part. That is, the coil patterns may have a width as large as possible in the magnetic material part.

Therefore, since the amount of current flowing in the coil patterns may be increased, the direct current (DC) resistance component in the coil may be significantly decreased. Therefore, power conversion efficiency may be increased, and the coil component may be used as a high inductance power inductor.

On the other hand, the core substrate may be formed to be as small as possible, in accordance with the size of the coil pattern, such that the overall size of the coil component may be significantly decreased.

Meanwhile, the present disclosure is not limited to the foregoing exemplary embodiment, and embodiments thereof may be variously applied and modified.

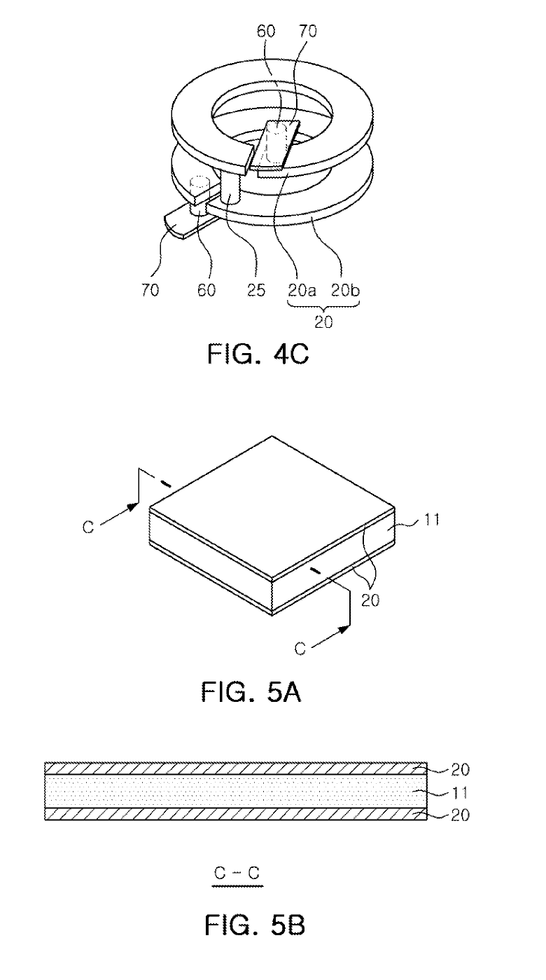

FIG. 4A is a perspective view schematically illustrating a coil component according to a second exemplary embodiment in the present disclosure. FIG. 4B is a cross-sectional view taken along line B-B of FIG. 4A. FIG. 4C is a perspective view schematically illustrating a coil assembly of the coil component illustrated in FIG. 4A. Here, since FIG. 4B is the cross-sectional view taken along line B-B of FIG. 4A, it may be preferable that only the connection conductor 25 connecting the internal conductors 20 to each other is illustrated in FIG. 4B and other through vias 60 are not illustrated in FIG. 4B. However, for convenience of explanation, all of the through vias 60 are illustrated in FIG. 4B.

Referring to FIGS. 4A through 4C, a coil component 200 according to the second exemplary embodiment may include an insulating material part 80 formed on the external surface of the magnetic material part 50. In addition, the external electrodes 70 may be formed on the insulating material part 80.

The insulating material part 80 may be formed in a manner in which the magnetic material part 50 is embedded therein, and the external electrodes 70 may be formed on the insulating material part 80 and be electrically connected to the internal conductors 20 of the coil assembly 10.

The external electrodes 70 may be provided as a pair of external electrodes on upper and lower surfaces of the insulating material part 80, respectively, and be electrically connected to both ends of the coil 20 and 25 by the through vias 60. That is, the internal conductors 20a and 20b disposed in the uppermost layer and the lowermost layer of the coil 20 and 25 may be electrically connected to the external electrodes 70 through the through vias 60 penetrating the magnetic material part 50 and the insulating material part 80.

The coil component 200 according to the exemplary embodiment includes the insulating material part 80, whereby the magnetic material part 50 may be protected from its external environment, and insulation between the coil component 200 and the external environment or an external element may be secured. In addition, the coil component 200 may be independently mounted on one surface of a circuit board or be independently embedded in the circuit board.

Meanwhile, the exemplary embodiment exemplifies a case in which the insulating material part 80 is formed on the entirety of the external surface of the magnetic material part 50. However, a configuration in the present disclosure is not limited thereto. That is, the insulating material part 80 may not be formed on the entirety of the external surface of the magnetic material part 50, but may be formed only on a portion of the external surface of the magnetic material part 50. For example, the insulating material part 80 may be formed on any one surface or both surfaces of the magnetic material part 50 or be only formed on a portion on which the external electrode 70 will be formed.

In addition, the insulating material part 80 according to the exemplary embodiment may contain a magnetic powder or a metal powder therein. In this case, the insulating material part 80 may also serve to shield an electromagnetic wave or noise.

Next, a manufacturing method of a coil component according to an exemplary embodiment in the present disclosure will be described.

FIGS. 5A through 10B are views illustrating a manufacturing method of the coil component according to the first exemplary embodiment in the present disclosure.

Referring to FIGS. 5A through 10B, in the manufacturing method of the coil component 100 (See FIG. 1), the core substrate 11 having metal layers 20 formed on two surfaces thereof may be prepared as illustrated in FIGS. 5A and 5B.

Here, the core substrate 11 may be an insulating substrate, and the metal layer 20 may be a copper thin film.

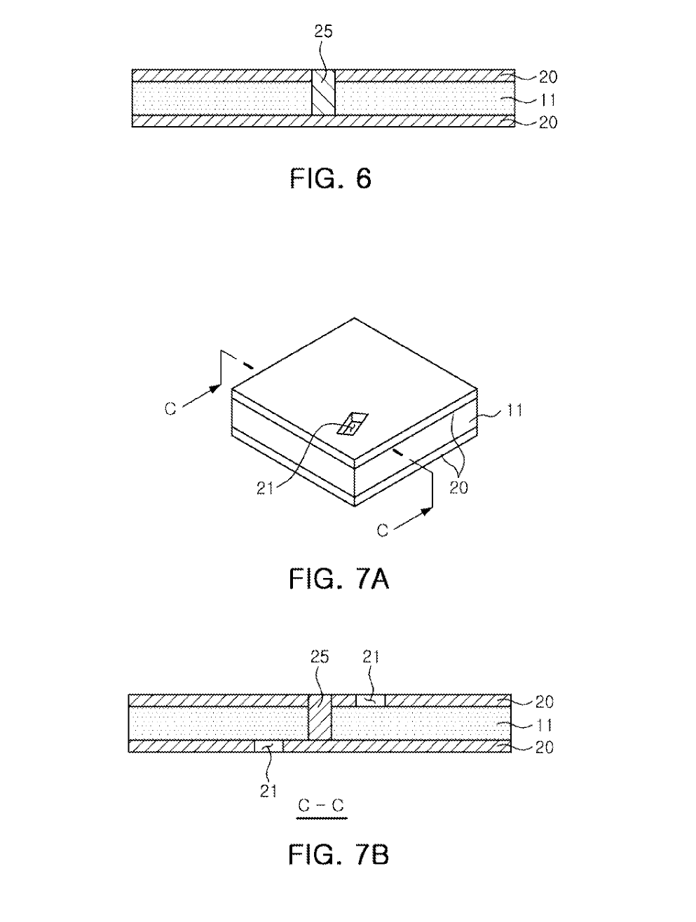

Then, as illustrated in FIG. 6, at least one conductive via, that is, the connection conductor 25, may be formed in the core substrate 11.

The connection conductor 25 may be formed by a general manufacturing method of conductive via. That is, the connection conductor 25 may be formed by forming a penetration hole using laser drilling, etching, or the like, and then filling the penetration hole with a conductive material by a method such as plating, or the like.

Then, as illustrated in FIGS. 7A and 7B, separation grooves 21 may be formed in the metal layers 20. Each separation groove 21 may be formed by removing a portion of the metal layer 20. Therefore, a bottom surface of the separation groove 21 may be formed by one surface of the core substrate 11.

The separation groove 21 may be provided to form a portion in which a pattern is disconnected in an internal conductor (that is, a coil pattern) to be subsequently formed. Therefore, the separation groove 21 may be formed to have a width equal to or larger than that of the coil pattern.

The separation grooves 21 according to the exemplary embodiment may be formed in both of the metal layers 20 on two surfaces of the core substrate 11. In addition, two separation grooves 21 may be formed in different positions in a vertical direction in order to complete a coil structure.

In more detail, the two separation grooves 21 may be formed in both sides adjacent to the connection conductor 25 based on the connection conductor 25, as illustrated in FIG. 7B. This may be clearly understood through the coil structure to be described below.

The separation grooves 21 may be formed by a method such as laser beam processing, etching, or the like.

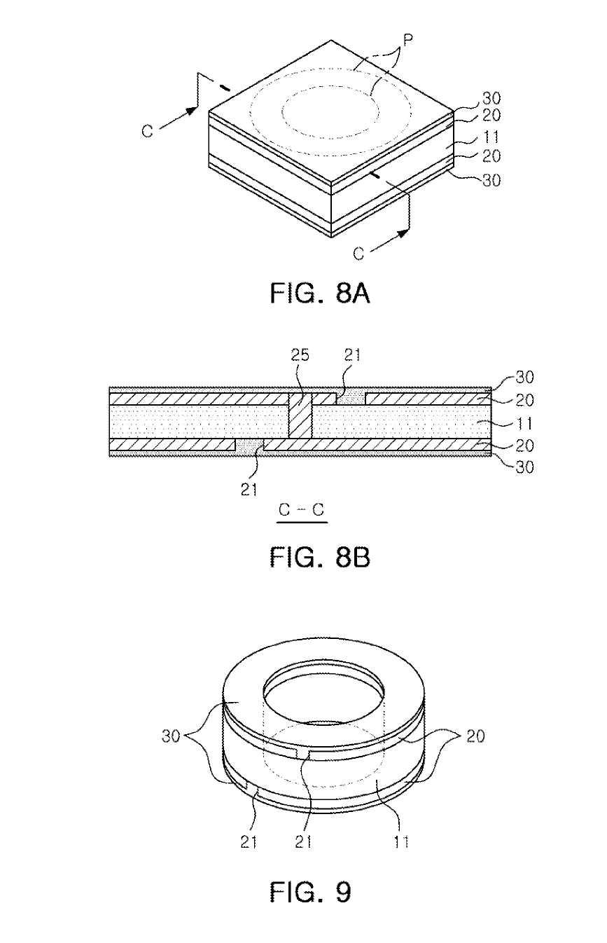

Then, as illustrated in FIGS. 8A and 8B, the insulating layers 30 may be respectively formed on external surfaces of the metal layers 20.

The insulating layers 30 may be formed by various methods such as applying an insulating material to surfaces of the metal layers 20, impregnating the core substrate 11 with an insulating material, and the like.

Here, the insulating layers 30 may also be filled in the interior of the separation grooves 21.

Then, as illustrated in FIG. 9, the core substrate 11 on which the metal layers 20 and the insulating layers 30 are formed may be cut to form a coil shape. The core substrate 11 may be cut by press-cutting. That is, after the core substrate 11 is disposed in a cutting apparatus, it may be cut along a cut line P (See FIG. 8A) by press-cutting to thereby be processed in a shape illustrated in FIG. 9.

The core substrate 11 is cut as described above, whereby only portions substantially forming the coil, that is, only the internal conductors 20, in the metal layers 20, may remain and all of the remaining portions may be removed.

In this process, the separation grooves 21 and the connection conductor 25 as described above may remain. The metal layers 20 remaining on the core substrate may be formed as the internal conductors 20 having a ring shape in which they are partially disconnected by the separation grooves 21 (See FIG. 2). In addition, the internal conductors 20 formed on two surfaces of the core substrate may be electrically connected to each other by the connection conductor 25 to form a continuous coil shape.

As described above, in the manufacturing method of the coil component 100 according to the exemplary embodiment, the coil structure may be completed by only a process of forming the conductive via and a single cutting process without a complicated process being performed to form a specific pattern on the core substrate. Therefore, the manufacturing of the coil component 100 may be facilitated.

Meanwhile, in the exemplary embodiment, since the internal conductor is formed in a circular shape, the substrate may also be cut in a circular ring shape. However, the configuration in the present disclosure is not limited thereto. That is, the shape of the core substrate may be formed in accordance with the shape of the coil. For example, in the case in which the internal conductor is formed in a rectangular ring shape, the substrate may also be cut in a rectangular ring shape.

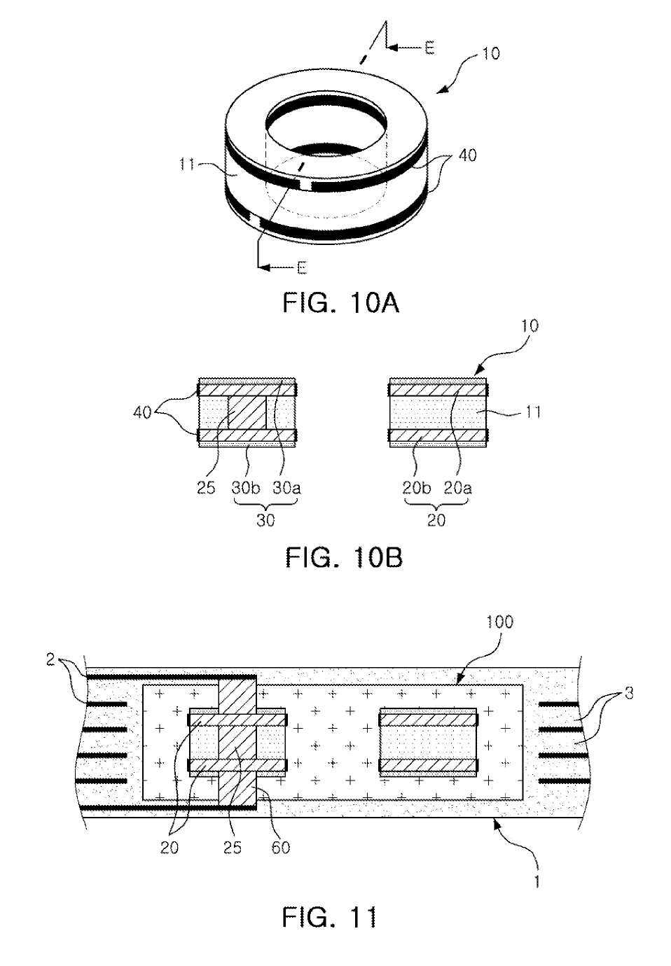

Then, as illustrated in FIGS. 10A and 10B, the insulating films 40 may be formed. The insulating films 40 may be formed on side surfaces of the internal conductors 20 exposed to the outside by the cutting process.

Each insulating film 40 according to the exemplary embodiment may be an oxide film. Therefore, in the case in which the internal conductor 20 is formed of copper (Cu), the insulating film 40 may be an oxide film formed of a copper oxide (CuO or CuO₂).

The insulating film 40 may be formed to have a thickness of several hundred nms to several ten μms. The thickness of the insulating film 40 may be determined depending on current, voltage, or the like, applied to the coil component.

Meanwhile, in the case in which the insulating film 40 needs to have a thickness greater than that of the oxide film, the insulating film 40 may be formed of a separate insulating material. For example, the insulating film 40 may be formed at the thickness greater than that of the oxide film by spraying or applying the insulating material onto an exposed portion of the internal conductor 20 (or an external surface of the oxide film) and then drying the insulating material, adhering an insulating film, or the like.

After the coil assembly 10 is completed by the process as described above, the magnetic material part 50 may be formed outside of the coil assembly 10 to complete the coil component 100 as illustrated in FIGS. 1 through 3.

The magnetic material part 50 may be formed by disposing the coil assembly 10 in a mold, filling the mold with a magnetic material in a paste form, and then curing the magnetic material or disposing the coil assembly 10 in a mold, stacking sheet-shaped magnetic materials on upper and lower surfaces of the substrate, and then compressing the magnetic material.

The coil component 100 formed by the process as described above may be used as the coil component 100 to be embedded in a substrate, in a semi-product state. This will be described below.

Meanwhile, the coil component 200 according to the foregoing second exemplary embodiment in the present disclosure illustrated in FIG. 4B may be manufactured by forming the insulating material part 80 on the external surface of the coil component 100 of FIG. 1, forming the through vias 60 penetrating the insulating material part 80 and the magnetic material part 50, and then forming the external electrodes 70 on the external surface of the insulating material part 80.

Here, the through vias 60 may electrically connect the external electrodes 70 and the internal conductors 20 of the coil assembly 10 to each other.

Meanwhile, the insulating material part 80 may be formed by applying an insulating material onto the external surface of the magnetic material part 50. However, the insulating material part 80 is not limited to being formed by the above-mentioned method, but may be formed by various other methods such as impregnating the coil component 100 of FIG. 1 in a liquid insulating material, adhering an insulating film to the external surface of the coil component 100, or the like.

In addition, the external electrodes 70 may be formed to have wide areas on surfaces of the insulating material part 80 and may be formed in various manners, if necessary. For example, the external electrodes 70 may be extended to other surfaces of the insulating material part 80.

In the manufacturing method of the coil component according to the exemplary embodiment configured as described above, the coil patterns are not formed by a method such as etching, or the like, as in the related art, but may be formed by cutting the core substrate by a pressing process. Therefore, a manufacturing process of the coil component may be simplified, such that cost and time required for manufacturing the coil component may be reduced.

In addition, in the related art, since coil patterns are generally formed by a method such as etching, there is a limitation in increasing widths of the coil patterns. However, in the manufacturing method of the coil component according to the exemplary embodiment, since the coil patterns are formed by cutting, the coil patterns may be formed to have the same width as that of the substrate.

Therefore, since the amount of current flowing in the coil patterns may be significantly increased, a DC resistance in the coil may be significantly decreased. Therefore, power conversion efficiency may be increased, and the coil component may be used as a high inductance power inductor.

Further, the coil component according to the exemplary embodiment in the present disclosure may be easily embedded in a substrate.

FIG. 11 is a cross-sectional view schematically illustrating a coil component-embedded substrate according to a third exemplary embodiment in the present disclosure. Here, it is preferable that the through vias 60 connected to the wiring patterns 2 of a coil component-embedded substrate 1 are not fully illustrated in FIG. 11 since they are disposed on a vertical plane different from that of the connection conductor 25 connecting the internal conductors 20 to each other. However, for convenience of explanation, the through vias 60 are illustrated in FIG. 11.

Referring to FIG. 11, the coil component-embedded substrate 1 according to the exemplary embodiment may include a plurality of insulating layers 3 and a plurality of wiring patterns 2 disposed between the insulating layers 3. In addition, the coil component-embedded substrate 1 according to the exemplary embodiment may include the coil component 100 embedded therein.

The coil component 100 embedded in the coil component-embedded substrate 1 may be in an intermediate-product state illustrated in FIG. 1. In addition, the coil patterns of the coil component 100 may be electrically connected to the wiring patterns 2 of the coil component-embedded substrate 1 by the through vias 60 penetrating both of the coil component-embedded substrate 1 and the coil component 100.

To this end, the coil component-embedded substrate 1 may be formed to have a thickness greater than that of the coil component 100 in the intermediate-product state in such a manner that the coil component 100 may be entirely embedded therein.

Meanwhile, a method of embedding the coil component 100 in the coil component-embedded substrate 1 may be performed as follows.

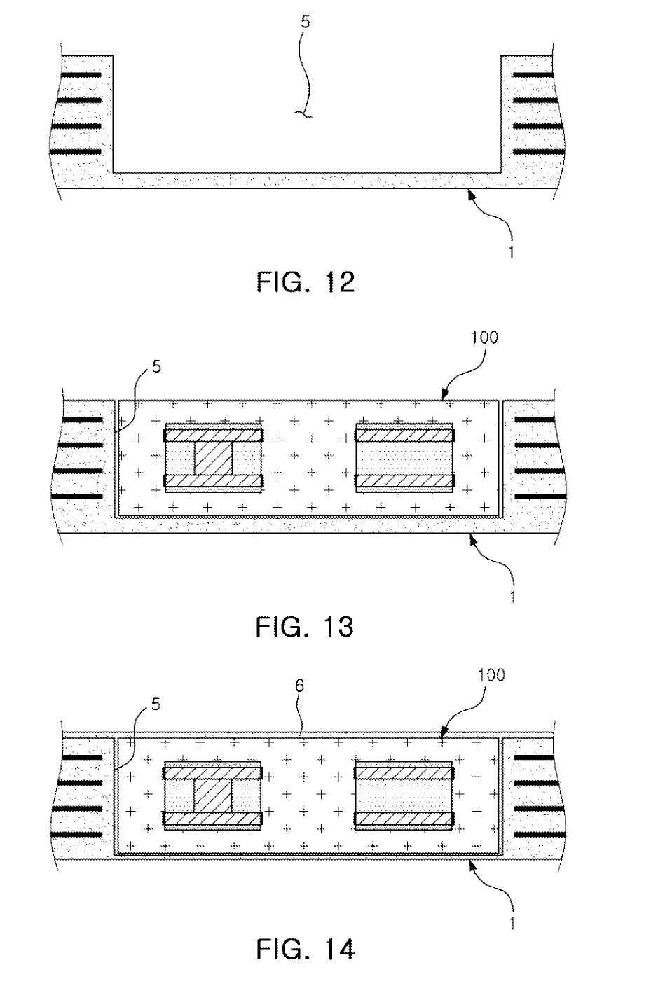

FIGS. 12 through 19 are views illustrating a manufacturing method of the coil component-embedded substrate illustrated in FIG. 11.

Referring to FIGS. 12 through 19, the substrate 1 having a cavity 5 formed therein may be first prepared, as illustrated in FIG. 12. Here, the substrate 1 may be a multilayer substrate and be in a state in which the manufacturing of the substrate is not completed.

Then, as illustrated in FIG. 13, the coil component 100 in the intermediate-product state may be inserted into the cavity 5. Therefore, the cavity 5 may be formed to have a size corresponding to that of the coil component 100. However, in the case in which components other than the coil component 100 are embedded in the cavity, the size of the cavity 5 may be increased.

Then, as illustrated in FIG. 14, an insulating material such as a resin, or the like, may entirely cover the coil component 100 simultaneously with filling the cavity 5 to thereby allow the coil component 100 to be embedded in the substrate 1.

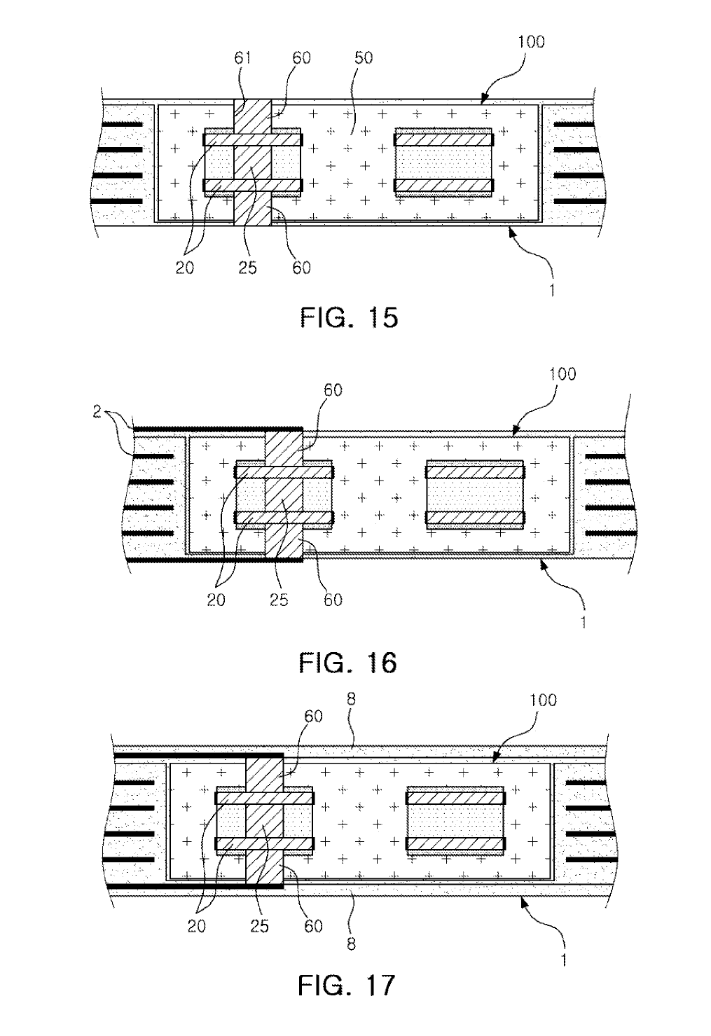

Then, as illustrated in FIG. 15, the through vias 60 may be formed in two surfaces of the coil component 100. Here, the through vias 60 may be formed by forming via holes 61 so as to penetrate both the substrate 1 and the coil component 100 and then filling the via holes 61 with a conductive material. Therefore, one end of each of the through vias 60 may be electrically connected to the internal conductors 20 of the coil component 100, respectively.

Meanwhile, it is preferable that the through vias 60 are not fully illustrated in FIGS. 15 through 18, since they are disposed on a vertical plane different from that of the connection conductor 25 connecting the internal conductors 20 to each other. However, for convenience of explanation, the through vias 60 are illustrated in FIGS. 15 through 18.

Then, as illustrated in FIG. 16, the wiring patterns 2 may be formed on the substrate. Here, the wiring patterns 2 may be electrically and physically connected to the other ends of the through vias 60. Therefore, the coil component 100 may be electrically connected to the wiring patterns 2 of the substrate through the through vias 60.

Then, as illustrated in FIG. 17, insulating layers 8 may be formed on the wiring patterns 2 to complete the coil component-embedded substrate 1 according to the exemplary embodiment.

Meanwhile, in the case in which the magnetic material part 50 of the coil component 100 is formed of an insulating material containing a metal powder, an electrical short-circuit may occur between the through vias 60 and the magnetic material part 50 of the coil component 100 due to the metal powder in a state illustrated in FIG. 15.

Therefore, in this case, the magnetic material part 50 and the through vias 60 need to be insulated from each other.

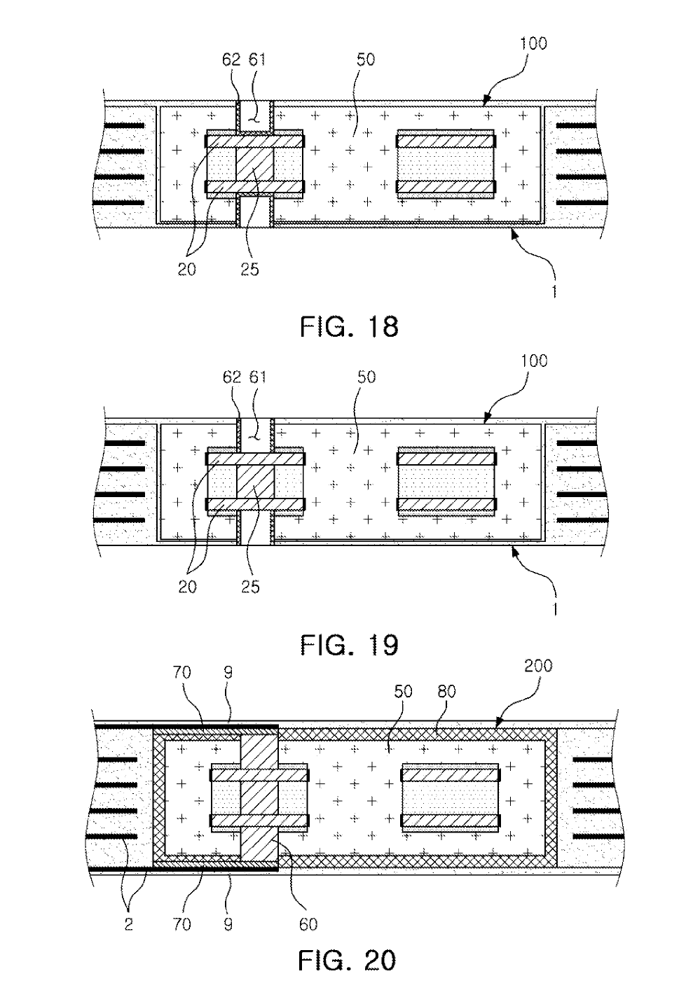

In more detail, after the via holes 61 for the through vias 60 are formed in the state illustrated in FIG. 14, insulating layers 62 may be formed on bottom surfaces and wall surfaces of the via holes 61, as illustrated in FIG. 18. Here, as the insulating layer 62, a solder resist, or the like, may be used.

Then, after the insulating layers 62 formed on the bottom surfaces of the via holes 61, that is, portions thereof formed on the internal conductors 20 may be removed as illustrated in FIG. 19, the through vias 60 may be formed in the via holes 61 as illustrated in FIG. 15.

Therefore, the through vias 60 may be electrically connected to the internal conductors 20 and be insulated from the magnetic material part 50 by the insulating layers 62.

Meanwhile, although the exemplary embodiment exemplifies a case in which the coil component 100 is entirely embedded in the coil component-embedded substrate 1, embodiments in the present disclosure are not limited thereto, and may be variously modified. For example, the coil component 100 may also be embedded in the coil component-embedded substrate 1 so that any one surface thereof is exposed to the outside of the coil component-embedded substrate 1 or both surfaces thereof are exposed to the outside of the coil component-embedded substrate 1.

FIG. 20 is a cross-sectional view schematically illustrating a coil component-embedded substrate according to a fourth exemplary embodiment in the present disclosure.

Referring to FIG. 20, a structure in which the coil component 200 illustrated in FIG. 4B is embedded in the coil component-embedded substrate 1 is shown. In this case, since the external electrodes 70 are formed in the coil component 200, the coil component 200 and the wiring patterns 2 of the coil component-embedded substrate 1 may be electrically connected to each other by only a process of inserting the coil component 200 into the coil component-embedded substrate 1 and further, forming the wiring patterns 2.

In addition, in order to protect the wiring patterns 2 and the coil component 200, protective insulating layers 9 may be formed on the wiring patterns 2 and the coil component 200. Here, as the protective insulating layer 9, a solder resist, or the like, may be used.

In the exemplary embodiment, the coil component 200 may be inserted into and coupled to the cavity having a penetration hole shape and formed in the coil component-embedded substrate 1, and may have two surfaces exposed to the outside of the coil component-embedded substrate 1. Therefore, the coil component-embedded substrate 1 may be formed to have a thickness substantially the same as or slightly greater than that of the coil component 200.

Therefore, even in a case in which the coil component 200 is embedded in the coil component-embedded substrate 1 according to the exemplary embodiment, the thickness of the coil component-embedded substrate 1 may be significantly decreased. In addition, a separate process of forming the through vias 60 (See FIG. 11) according to the third exemplary embodiment in the present disclosure described above may be omitted in a process of embedding the coil component 200, the coil component-embedded substrate may be easily manufactured.

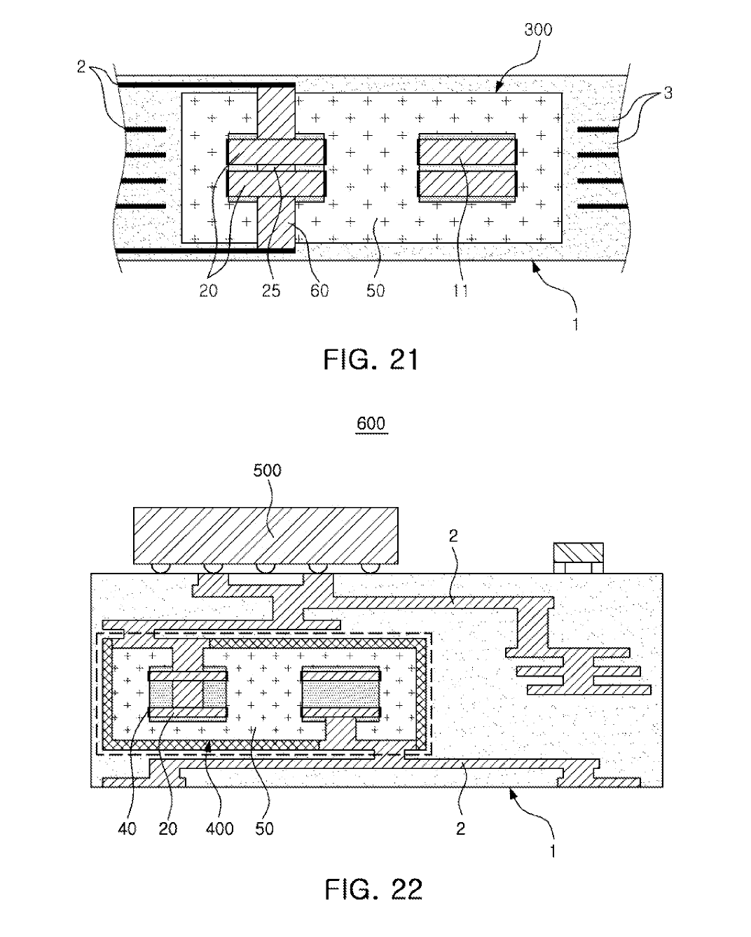

FIG. 21 is a cross-sectional view schematically illustrating a coil component-embedded substrate according to a fifth exemplary embodiment in the present disclosure.

Referring to FIG. 21, in a coil component 300 according to the exemplary embodiment, the internal conductors 20 may be formed to have a thickness greater than that in the coil components according to foregoing exemplary embodiments in the present disclosure. Therefore, the core substrate 11 between the internal conductors 20 may be formed to have a significantly reduced thickness.

In the case in which the internal conductors 20 are formed to have an increased thickness as described above, external areas of the internal conductors 20 may be increased. Therefore, since an amount of current flowing in the coil patterns may be further increased, a DC resistance component generated in the coil may be significantly decreased.

In addition, the magnetic material parts 50 respectively disposed above and below the internal conductors 20, may be formed to have a thickness greater in the coil component 300 according to the exemplary embodiment than in the coil components according to exemplary embodiments in the present disclosure described above. For example, the magnetic material parts 50 respectively disposed above and below the internal conductors 20 may be formed to have a thickness of 50 μm or more.

In this case, a cross-sectional area of the magnetic material part 50 is increased, whereby the majority of magnetic fluxes formed in the magnetic material part 50 may be present in the magnetic material part 50 without being easily saturated or being leaked to the outside.

Therefore, an influence of the leaked magnetic flux on the coil component-embedded substrate 1 or other electronic elements mounted on the coil component-embedded substrate 1 may be significantly decreased.

FIG. 22 is a cross-sectional view schematically illustrating a voltage adjustment module according to an exemplary embodiment in the present disclosure.

Referring to FIG. 22, a voltage adjustment module 600 according to the exemplary embodiment may be used in an envelope tracking (ET) power amplifier. That is, the voltage adjustment module 600 may adjust an amount of voltage provided to a radio frequency (RF) power amplifier depending on a magnitude of a radio signal in the ET power amplifier.

The voltage adjustment module 600 may include the coil component-embedded substrate 1, a power inductor 400 embedded in the coil component-embedded substrate 1, and a voltage adjusting element 500 mounted in the coil component-embedded substrate 1. In addition, the voltage adjustment module 600 may further include other electronic elements, if necessary.

Here, the power inductor 400 may be one of the coil components as described above, and the coil component-embedded substrate 1 may be one of the coil component-embedded substrates having the above-mentioned coil components embedded therein.

In addition, the voltage adjusting element 500 may adjust the amount of voltage provided to the RF power amplifier depending on a magnitude of the radio signal.

In the power inductor 400 of the voltage adjustment module 600 configured as described above, the magnetic material parts 50 respectively disposed above and below the internal conductors 20, may be formed to have a thickness of 50 μm or more. In addition, the internal conductors 20 and the magnetic material part 50 may be insulated from each other by the insulating films 40.

Meanwhile, the coil component-embedded substrate according to the present disclosure is not limited to those of the exemplary embodiments described above, and may be variously modified. For example, the coil component-embedded substrate may be configured to have the coil component embedded therein in a manner in which a portion of the coil component protrudes from one surface of the coil component-embedded substrate.

In addition, although the exemplary embodiment exemplifies a case in which only the coil component is embedded in the coil component-embedded substrate, various passive elements and active elements may also be embedded in the coil component-embedded substrate, in addition to the coil component.

As set forth above, in a manufacturing method of a coil component according to exemplary embodiments in the present disclosure, coil patterns are not formed by a method such as an etching method, or the like, as in the related art, and may be formed by a method of cutting a substrate. Therefore, a process of manufacturing the coil component may be simplified, such that costs and time required for manufacturing the coil component may be decreased.

In addition, in the related art, since coil patterns are generally formed by a method such as the etching method, there is a limitation in increasing widths of the coil patterns. However, in the manufacturing method of a coil component according to exemplary embodiments in the present disclosure, since the coil patterns may be formed by the cutting method, the coil patterns may be formed to have the same width as that of the substrate.

Therefore, in the coil component according to exemplary embodiments in the present disclosure, since an amount of current flowing in the coil patterns may be significantly increased, a DC resistance component generated in the coil may be significantly decreased. Therefore, power conversion efficiency may be increased, and the coil component may be used as a high inductance power inductor.

While exemplary embodiments have been shown and described above, it will be apparent to those skilled in the art that modifications and variations could be made without departing from the scope of the invention as defined by the appended claims.

What is claimed is:

1. A coil component comprising:
at least one core substrate;
at least one internal conductor on at least one surface of the core substrate; and
a magnetic material part outside of the core substrate,
wherein the internal conductor has a width at least the same as that of the core substrate.

2. The coil component of claim 1, wherein the core substrate and the internal conductor are in a ring shape.

3. The coil component of claim 1, wherein the magnetic material part embeds the core substrate and the internal conductor therein.

4. The coil component of claim 1, wherein the internal conductor includes a plurality of internal conductors respectively on two surfaces of the core substrate, and
the internal conductors are electrically connected to each other by at least one connection conductor.

5. The coil component of claim 4, wherein the connection conductor is in a shape of a conductive via penetrating the core substrate.

6. The coil component of claim 1, further comprising: an insulating layer between the internal conductor and the magnetic material part.

7. The coil component of claim 1, further comprising: an insulating film between the internal conductor and the magnetic material part.

8. The coil component of claim 1, further comprising: an insulating layer between one surface of the internal conductor and the magnetic material part and an insulating oxide film between a side surface of the internal conductor and the magnetic material part.

9. The coil component of claim 1, wherein the magnetic material part is made of an insulating material containing a magnetic powder or a metal powder.

10. The coil component of claim 1, further comprising:
an insulating material part on an external surface of the magnetic material part;
at least one external electrode on an external surface of the insulating material part; and
at least one through via electrically connecting the internal conductor and the external electrode to each other.

11. The coil component of claim 10, wherein the external electrode is on upper and lower surfaces of the insulating material part.

12. A coil component comprising:
at least one core substrate;
at least one internal conductor on at least one surface of the core substrate; and
a magnetic material part outside of the core substrate,
wherein an external peripheral edge and an inner peripheral edge of the internal conductor are at the same positions as those of the core substrate.

13. A manufacturing method of a coil component, comprising:
preparing a core substrate having a metal layer formed on at least one surface thereof;
processing the core substrate in a ring shape by cutting the core substrate by a pressing method; and
forming a magnetic material part outside of the core substrate having the ring shape.

14. The manufacturing method of claim 13, further comprising: after the preparing of the core substrate, forming multilayer patterns by processing the core substrate.

15. The manufacturing method of claim 14, wherein the forming of the multilayer patterns includes:
electrically connecting metal layers respectively formed on both surfaces of the core substrate to each other by forming a connection conductor in the core substrate; and
forming separation grooves by removing portions of the metal layers.

16. The manufacturing method of claim 15, wherein in the forming of the separation grooves, the respective separation grooves are formed in two metal layers while being provided in both sides of the connection conductor.

17. The manufacturing method of claim 15, further comprising: after the forming of the separation grooves, forming insulating layers on external surfaces of the metal layers.

18. The manufacturing method of claim 13, further comprising: after the processing of the core substrate, forming an insulating film on an external surface of an internal conductor formed by cutting the metal layer.

19. The manufacturing method of claim 18, wherein in the forming of the insulating film, an oxide film is formed on an exposed surface of the internal conductor.

20. The manufacturing method of claim 18, further comprising: after the forming of the magnetic material part outside of the core substrate, forming an insulator layer on an external surface of the magnetic material part.

21. The manufacturing method of claim 20, further comprising: after the forming of the insulator layer, forming at least one through via in the insulator layer, the through via being electrically connected to the internal conductor; and
forming at least one external electrode on an external surface of the insulator layer, the external electrode being electrically connected to the through via.

22. A coil component-embedded substrate comprising:
at least one insulating layer; and
a coil component including a core substrate having an internal conductor on at least one surface thereof and a magnetic material part formed outside of the core substrate and embedded in the insulating layer, the internal conductor having a width at least the same as that of the core substrate.

23. A voltage adjustment module comprising:
a substrate;
a power inductor including a core substrate having an internal conductor on at least one surface thereof and a magnetic material part outside of the core substrate and embedded in the substrate, the internal conductor having a width at least the same as that of the core substrate; and
at least one voltage adjusting element mounted on the substrate and electrically connected to the power inductor.

24. The voltage adjustment module of claim 23, wherein the voltage adjusting element adjusts an amount of voltage provided to a radio frequency (RF) power amplifier depending on a magnitude of a radio signal in an envelope tracking (ET) power amplifier.

25. The voltage adjustment module of claim 24, wherein portions of the magnetic material part disposed above and below the core substrate respectively have a thickness of 50 μm or more.

26. A coil component comprising:
at least one cylindrical core substrate;
internal sheet-like conductors on opposing end surfaces of the core substrate; and
a magnetic material part outside of the core substrate,
wherein the internal conductors have an outer diameter at least as large as that of the core substrate.

27. The coil component of claim 26, wherein the core substrate and the internal conductors are in a ring shape.

28. The coil component of claim 26, wherein the internal conductors are electrically connected to each other by at least one connection conductor.

29. The coil component of claim 28, wherein the connection conductor is in a shape of a conductive via penetrating through the core substrate.
